(19) United States
(12) Patent Application Publication
(10) Pub. No.: US 2010/0181615 A1
(43) Pub. Date: Jul. 22, 2010

(54) SEMICONDUCTOR DEVICE

(75) Inventor: Yoshinori IKEBUCHI, Tokyo (JP)

Correspondence Address: YOUNG & THOMPSON, 209 Madison Street, Suite 500, Alexandria, VA, 22314, US

(73) Assignee: ELPIDA MEMORY, INC., Tokyo (JP)

(21) Appl. No.: 12/690,620

(22) Filed: Jan. 20, 2010

(30) Foreign Application Priority Data
Jan. 20, 2009 (JP) 2009-009857

(51) Int. Cl. H01L 29/78

(52) U.S. Cl. 257/329; 257/E29.262

(57) ABSTRACT

There is provided a semiconductor device in which an upper main electrode region of a 3D pillar SGT includes a selective epitaxial growth semiconductor film, at least two adjacent 3D pillar SGTs are interconnected in parallel with each other by joining the selective epitaxial growth semiconductor films together, thereby the need for providing an interconnect layer for interconnecting 3D pillar SGTs in parallel with each other is eliminated.

### BACKGROUND OF THE INVENTION

1. Field of the Invention

The present invention relates to a semiconductor device including vertical insulated-gate transistors having a three-dimensional structure and a method for fabricating the semiconductor device and, in particular, to a semiconductor device including vertical insulated-gate transistors interconnected in parallel and vertical insulated-gate transistors not interconnected in parallel and a method for fabricating the semiconductor device.

2. Description of the Related Art

Vertical insulated-gate transistors, in particular, three-dimensional vertical surrounding gate transistors (hereinafter referred to as 3D pillar SGTs) have been proposed as transistors for semiconductor devices.

The 3D pillar SOT has a structure in which the source, gate, and drain are disposed in the direction normal to the surface of the substrate and the gate surrounds a semiconductor pillar which functions as a channel. Accordingly, the 3D pillar SGT occupies a significantly smaller area than a planar MOSFET and is highly expected to be applied to DRAMs, flash EEPROMs, and CMOSs.

A 3D pillar SGT structure can be fabricated as described in JPA-2008-66721, for example. Pillar masks in a pattern of semiconductor pillars are formed on the surface of a semiconductor substrate and anisotropic etching such as RIE or plasma etching is applied to the semiconductor substrate as in conventional trench formation to form semiconductor pillars. Then, ions are implanted into the top portion of the semiconductor pillars and into the region of the surface of the semiconductor substrate between the semiconductor pillars to form diffusion layers which will act as source/drain regions. A gate insulating film is formed on the entire surface and then a conductive material such as polysilicon is deposited on the entire surface to form a film from which a gate electrode will be formed. The polysilicon film is subjected to anisotropic etching such as RIE to form a gate electrode around the side surface of each semiconductor pillar to complete an SGT structure.

To fabricate circuitry of a semiconductor device with 3D pillar SGTs, a plural of 3D pillar SGTs are interconnected in parallel with each other in locations where a large driving current is required. Connecting contacts to all of such individual 3D pillar SGTs requires provision of an interconnect layer for connecting the contacts in parallel. The provision of the interconnect layer for the parallel connection places significant constraints on the layout of interconnects with other lines and elements.

### SUMMARY

At the stage after the top of semiconductor pillars of 3D pillar SGTs to be interconnected in parallel with each other is exposed, a semiconductor (silicon) layer is laterally grown by using selective epitaxial growth to form a continuous upper diffusion layer.

In particular, according to one exemplary embodiment, there is provided a semiconductor device including a vertical insulated-gate transistor, vertical insulated-gate transistor comprising: a pillar semiconductor portion provided on a principal surface of a semiconductor substrate; a gate electrode provided around a side surface of the pillar semiconductor portion with a gate insulating film between the side surface and the gate electrode; and main electrode regions each provided upper and bottom portions of the pillar semiconductor; wherein the upper main electrode region of the transistor comprises a selective epitaxial growth semiconductor film and at least adjacent two of the transistors are interconnected in parallel with each other by joining the selective epitaxial growth semiconductor films of the transistors together.

Since the transistors interconnected in parallel with each other can share a contact connecting to the upper main electrode region (the upper diffusion layer), only one contact need to be provided for those transistors. Furthermore, the upper main electrode regions of the 3D pillar SGTs can be interconnected in parallel without needing an interconnect layer. Accordingly, positional constraints can be eased and the flexibility of layout can be increased.

### BRIEF DESCRIPTION OF THE DRAWINGS

The above features and advantages of the present invention will be more apparent from the following description of certain preferred embodiments taken in conjunction with the accompanying drawings, in which:

FIG. 1 is schematic cross-sectional views illustrating subject parts of a semiconductor device according to one exemplary embodiment, in which FIG. 1(A) illustrates a common upper diffusion layer type and FIG. 1(B) illustrates isolated upper diffusion layer type;

FIG. 2 is top views of the subject parts of the semiconductor device shown in FIG. 1;

FIGS. 3 to 7 are schematic cross-sectional views illustrating a semiconductor device fabricating process according to one exemplary embodiment;

FIG. 8 is schematic cross-sectional views illustrating subject parts of a semiconductor device according to another exemplary embodiment, in which FIG. 8(A) illustrates a common upper diffusion layer type and FIG. 8(B) illustrates an isolated upper diffusion layer type;

FIG. 9 is top views of the subject parts of the semiconductor device shown in FIG. 8; and

FIGS. 10 to 12 are schematic cross-sectional views illustrating a semiconductor device fabricating process according to another exemplary embodiment.

### DETAILED DESCRIPTION OF THE REFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purpose.

One feature of the present invention is that at least two adjacent vertical insulated-gate transistors are interconnected in parallel with each other by joining selective epitaxial growth semiconductor films that form upper main electrode regions of the two adjacent vertical insulated-gate transistors together (hereinafter such transistors are referred to as common upper diffusion layer type). Another feature of the present invention is that at least two adjacent vertical insulated-gate transistors are not interconnected in parallel with each other in which selective epitaxial growth semiconductor films that form upper main electrode regions of the two adjacent vertical insulated-gate transistors are not joined together (hereinafter such transistors are referred to as isolated upper diffusion layer type) and the selective epitaxial growth semiconductor films of the common upper diffusion layer type and the isolated upper diffusion layer type are formed at the same time.

Exemplary embodiments will be described with respect to specific examples. However, the present invention is not limited to these exemplary embodiments.

### First Exemplary Embodiment

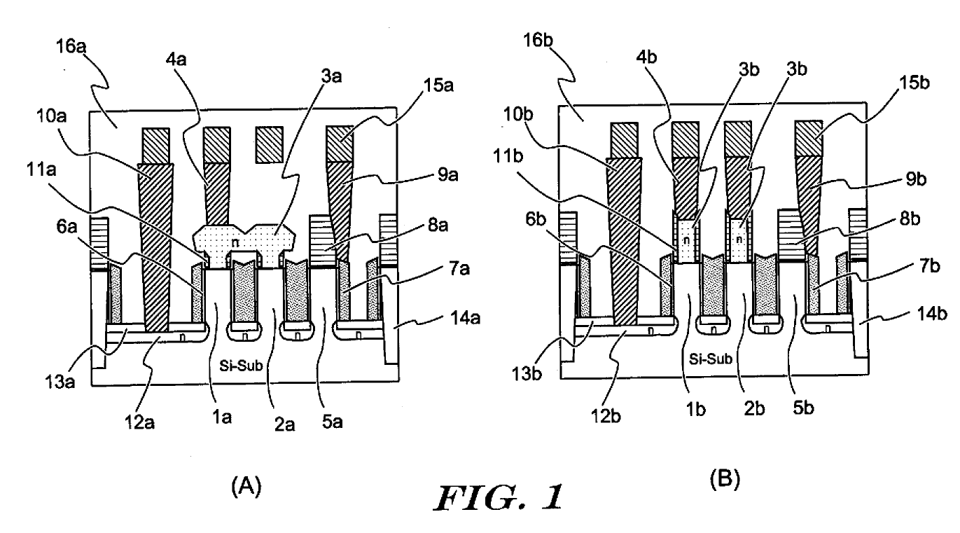

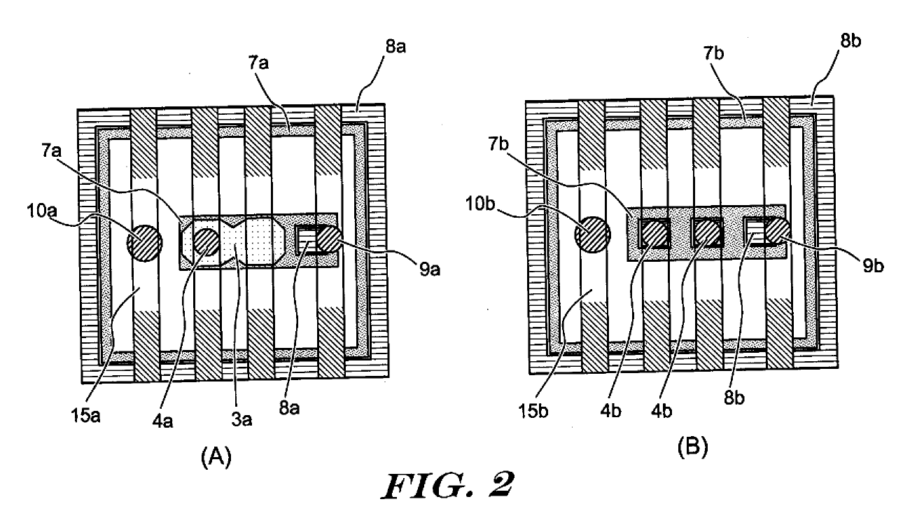

FIG. 1 illustrates cross-sectional views of a semiconductor device according to one exemplary embodiment. FIG. 2 illustrates top views of the semiconductor device shown in FIG. 1 viewed from above through an interlayer oxide film. The left part (A) of each of FIGS. 1 and 2 illustrates parallely interconnected 3D pillar SGTs of the common upper diffusion layer type. Pillar semiconductor portions (hereinafter referred to as silicon pillars) 1a and 2a provided on the principal surface of the semiconductor substrate are channels of the 3D pillar SGTs interconnected in parallel with each other. Upper main electrode region (upper diffusion layer) 3a is a selective epitaxial growth semiconductor film and is continuous. Accordingly, the two transistors can be driven by providing only one upper diffusion layer contact 4a.

On the other hand, the right part (B) of each of FIGS. 1 and 2 illustrates 3D pillar SGTs of the isolated upper diffusion layer type that are not to be parallely interconnected. Reference numerals in the figures denotes the following elements: 5 denotes gate contact silicon pillar, 6 denotes gate insulating film, 7 denotes gate electrode (polysilicon gate), 8 denotes pillar mask nitride film, 9 denotes gate contact, 10 denotes lower diffusion layer contact, 11 denotes sidewall nitride film, 12 denotes lower main electrode region (lower diffusion layer), 13 denotes lower oxide film, 14 denotes STI, 15 denotes tungsten interconnect, and 16 denotes interlayer insulating oxide film. Letter “a” is added to the reference numerals of the elements shown in (A) and “b” is added to the reference numerals of the elements shown in (B). These letters will be omitted in cases where the elements are described collectively.

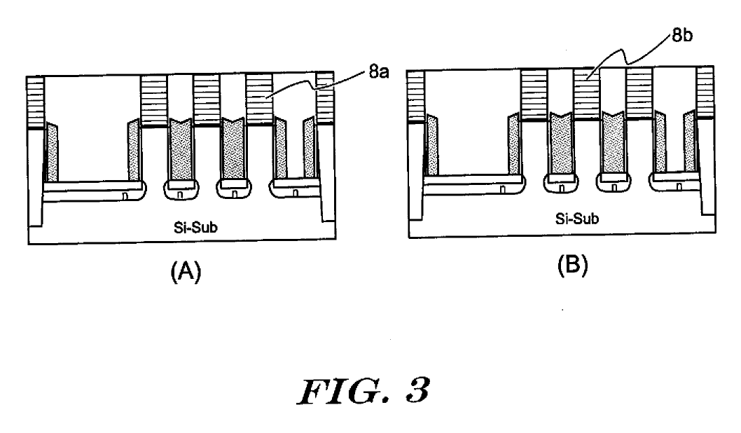

A method for fabricating the semiconductor device shown in FIG. 1 will be described with reference to FIGS. 3 to 7.

At the state shown in FIG. 3, the 3D pillar SGTs except the upper diffusion layer have been already formed by using a well known method. Pillar mask nitride film 8 for silicon pillar processing remains on top of the silicon pillars and inter-pillar oxide film is planarized by using pillar mask nitride film 8 as an etching stopper.

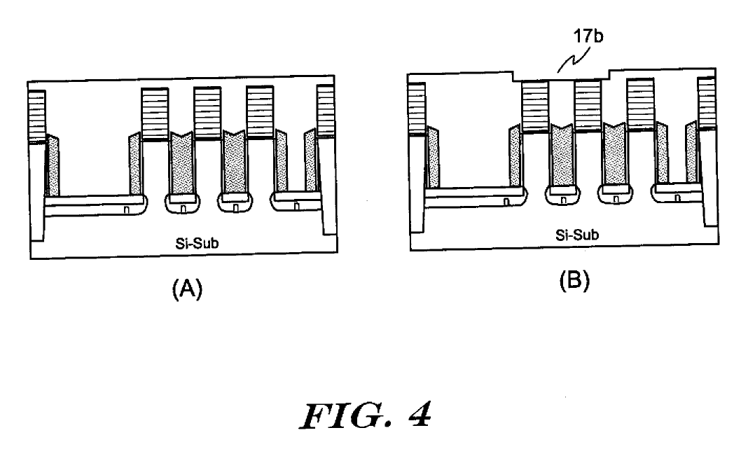

A thin oxide film is formed as illustrated in FIG. 4, then a lithography mask (not shown) and anisotropic etching are used to shallowly etch only part of the oxide film on the silicon pillars (1b, 2b) that are not to be parallely interconnected to form opening 17b to expose pillar mask nitride film 8b (FIG. 4(B)).

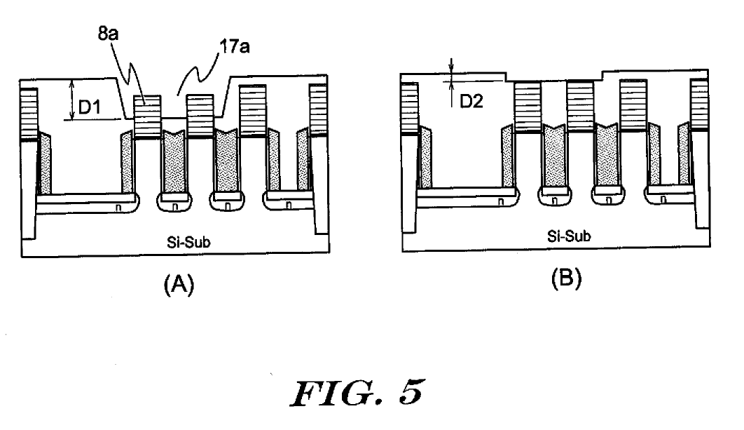

As shown in FIG. 5(A), a lithography mask and anisotropic etching are used to etch only part on the silicon pillars (1a, 1b) to be parallely interconnected more deeply than in the opening shown in FIG. 4(B) to form opening 17a. That is depth D1 of opening 17a is greater than depth D2 of opening 17b.

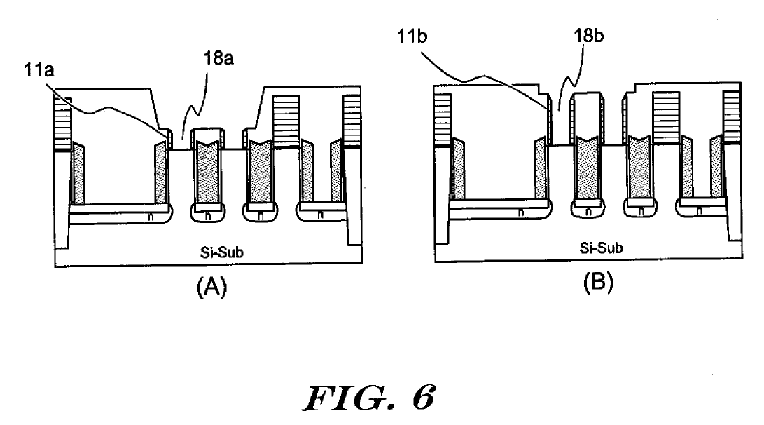

Pillar mask nitride film 8 is removed by using hot phosphoric acid, then sidewall nitride film 11 is formed by using LP nitride film growth and dry etch-back, thereby forming hole 18 defined by sidewall nitride film 11 as shown in FIG. 6.

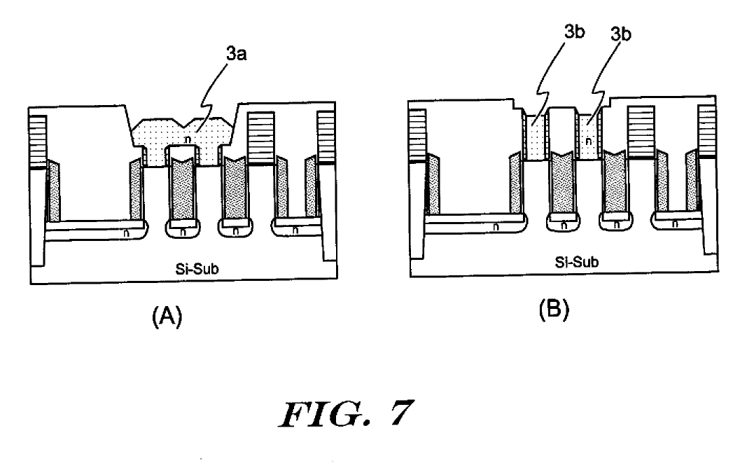

After selective epitaxial growth as illustrated in FIG. 7, arsenic ions are implanted and rapid thermal annealing (RTA) is applied to form an upper diffusion layer.

The selective epitaxial growth may be performed by introducing dichlorosilane (DCS) at a flow rate of 70 sccm, HCl at a flow rate of 40 sccm, and H₂ at a flow rate of 19 slm at a temperature of 780° C. and a pressure of 1.33 kPa (10 Torr).

For the common upper diffusion layer type, the depth of hole 18a defined by sidewall nitride film 11a is smaller than the amount of the epitaxial growth. Accordingly, the film grows not only vertically but also laterally so that the upper diffusion layer becomes continuous. For the isolated upper diffusion layer type, the depth of hole 18b defined by sidewall nitride film 11b is greater than or equal to the amount of epitaxial growth. Accordingly the selective epitaxial growth film does not laterally grow and transistors are kept isolated. In this way, portions of the upper diffusion layer that are parallely interconnected and portions of the upper diffusion layer that are not interconnected parallely can be readily formed for the common upper diffusion layer type and the isolated upper diffusion layer type by optimizing the depths of holes 18 on the silicon pillars according to the distance between adjacent silicon pillars.

At the subsequent stage, interlayer insulating oxide film 16 is formed by using a known method to form contacts and interconnects as illustrated in FIG. 1.

In a variation of the exemplary embodiment, hole 18a is not formed for a common upper diffusion layer type. That is, for the common upper diffusion layer type, the bottom of opening 17a can be the tops of silicon pillars 1a, 2a and an upper diffusion layer can be laterally grown directly from the tops of silicon pillars 1a, 2a by selective epitaxial growth to join the portions of the upper diffusion layer together. For the isolated upper diffusion layer type, the depth of hole 18b is not limited to a value greater than or equal to the amount of epitaxial growth. The depth may be smaller than the amount of epitaxial growth, provided that the laterally grown diffusion films do not join together, so that transistors can be kept isolated.

### Second Exemplary Embodiment

3D pillar SGTs with a common upper diffusion layer and 3D pillar SGTs with isolated upper diffusion layers can be formed at the same time by varying the distance between 3D pillar SGTs.

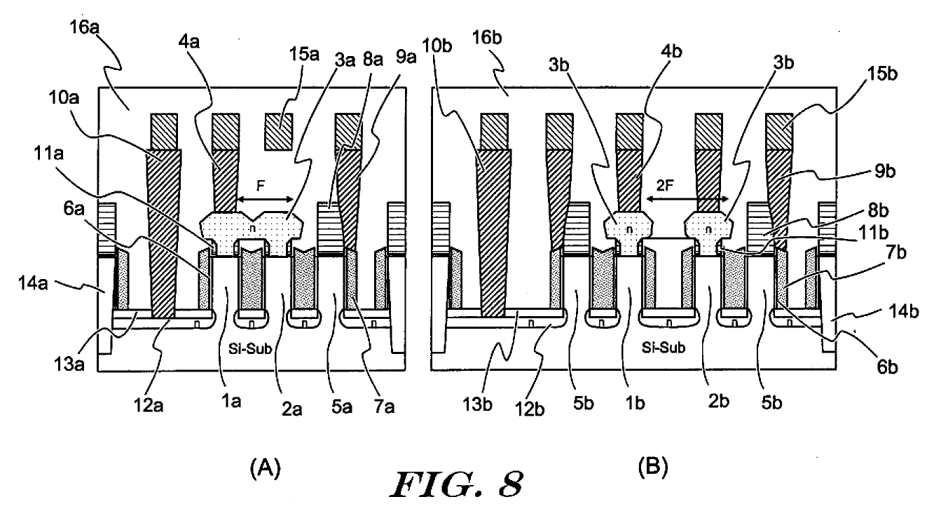

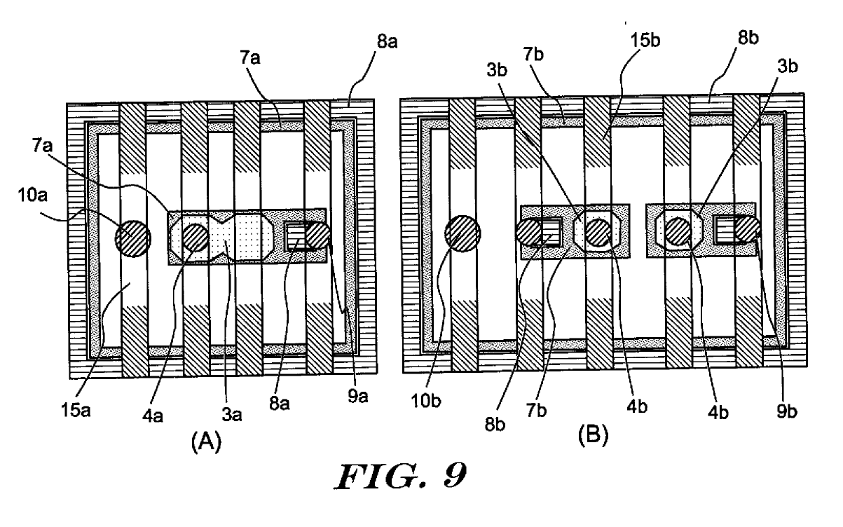

As shown in FIG. 8, for transistors to have a common upper diffusion layer, silicon pillars 1a and 2a are disposed at distance F from each other; for transistors not to have a common upper diffusion layer, silicon pillars 1b and 2b are disposed at a greater distance than F, for example a distance of 2F, from each other. FIG. 9 is a plan view of the semiconductor device shown in FIG. 8.

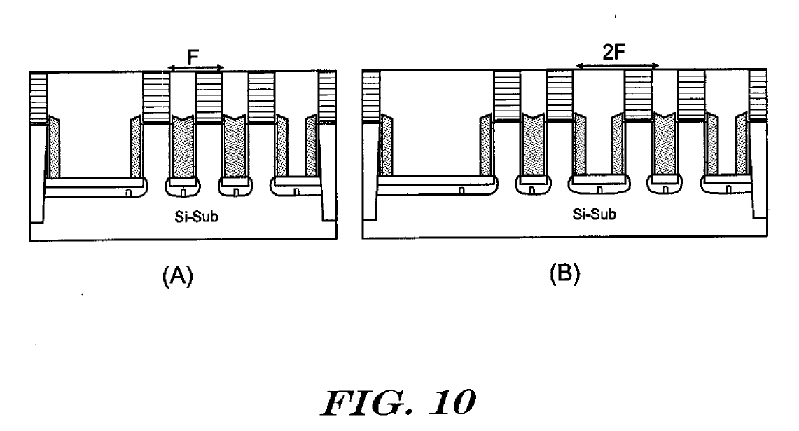

A method for fabricating the semiconductor device shown in FIG. 8 will be described with reference to FIGS. 10 to 12. As in the exemplary embodiment described above, 3D pillar SGTs have been formed as shown in FIG. 10 except an upper diffusion layer.

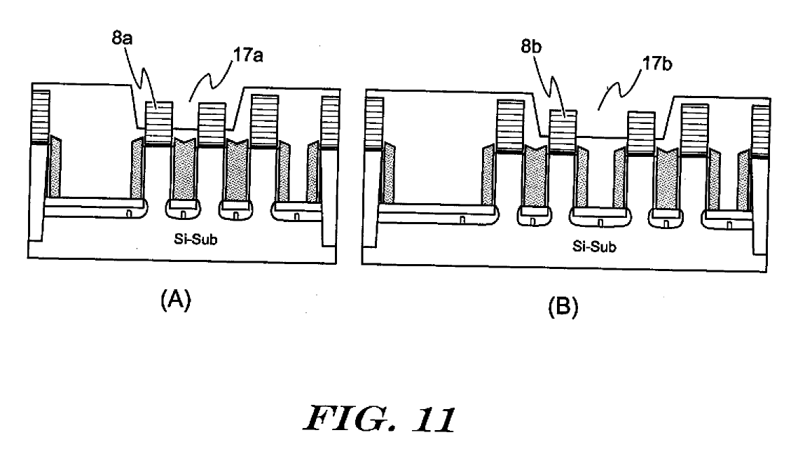

As shown in FIG. 11, a thin oxide film is formed and then lithography and anisotropic etching are applied only to areas on the tops of silicon pillars (1, 2) that will function as channels to form opening 17 to expose pillar mask nitride film 8. In this example, openings 17a and 17b have the same depth.

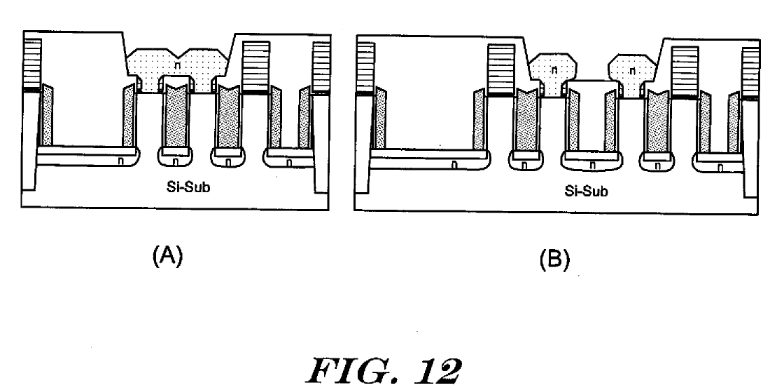

Then, as in the first exemplary embodiment, pillar mask nitride film 8 is removed, then sidewall nitride film 11 is formed, followed by selective epitaxial growth as shown in FIG. 12. Since the lateral distance over which the selective epitaxial growth can extend is limited, only upper diffusion layer 3a of closely spaced vertical transistors of the common upper diffusion layer type becomes continuous and common to those transistors.

Since the silicon pillars (1b, 2b) that will act as channels of the isolated upper diffusion layer type are largely spaced in this example, polysilicon gate 7b is not continuous between silicon pillars 1b and 2b and gate contact pillar 5b is provided adjacently to each polysilicon gate 7b. However, the exemplary embodiment is not limited to this. Gate contact pillar 5b can be provided between silicon pillars 1b and 2b and at the same time silicon pillars 1b and 2b can be spaced apart by optimizing the locations of gate contacts 9b. Furthermore, selective epitaxial growth can be performed in openings where holes are not formed for the common upper diffusion layer type or for both of the common upper diffusion layer and isolated upper diffusion layer types in the present exemplary embodiment.

While the examples in which two adjacent transistors are interconnected in parallel with each other have been described, more than two transistors may be interconnected in parallel.

Transistors to which the present invention can be applied are not limited to 3D pillar SGTs in which a gate electrode surrounding a silicon pillar is formed via a gate insulating film. The present invention can be applied to vertical insulated-gate transistors in general that include upper and lower main electrode regions disposed vertically.

(Further exemplary embodiment 1) A semiconductor device fabrication method comprising:

forming a plurality of pillar semiconductor portions including at least two adjacent pillar semiconductor portions on a principal surface of the semiconductor substrate;

forming a gate electrode around a side surface of each of the pillar semiconductor portions via a gate insulating film and a lower main electrode region at the bottom of the pillar semiconductor portion and then depositing an interlayer insulating film on the entire surface of the semiconductor substrate;

exposing the top surface of the pillar semiconductor portions;

selectively epitaxial-growing a semiconductor film from the top surface of the exposed pillar semiconductor portions so that the selective epitaxial growth semiconductor films on at least two adjacent pillar semiconductor portions are joined together; and

implanting impurity ions into the selective epitaxial growth semiconductor film to form an upper main electrode region of the transistors interconnected in parallel with each other.

(Further exemplary embodiment 2) The semiconductor device fabrication method according to Further exemplary embodiment 1, further forming at least two adjacent vertical insulated-gate transistors which include a selective epitaxial growth semiconductor film as an upper main electrode region and are not interconnected in parallel with each other.

(Further exemplary embodiment 3) The semiconductor device fabrication method according to Further exemplary embodiment 2, wherein the selective epitaxial growth semiconductor film of the transistors not interconnected in parallel with each other is formed at the same time as the selective epitaxial growth semiconductor film of the transistors interconnected in parallel with each other;

the exposing the top surface of the pillar semiconductor portions comprises forming an opening in a region including at least two adjacent pillar semiconductor portions in an interlayer insulating film covering the top of the pillar semiconductor portions and forming a hole exposing the top surface of the pillar semiconductor portions in the opening; and

the depth of the hole on the top of the pillar semiconductor portions of the transistors interconnected with each other is smaller than the amount of epitaxial growth and the depth of the hole on the top of the pillar semiconductor portions of the transistors not interconnected in parallel with each other is greater than or equal to the amount of epitaxial growth.

(Further exemplary embodiment 4) The semiconductor device fabrication method according to Further exemplary embodiment 3, wherein:

the forming a plurality of pillar semiconductor portions including at least two adjacent pillar semiconductor portions on the principal surface of the semiconductor substrate comprises forming a nitride film mask on the principal surface of a semiconductor substrate and etching the semiconductor substrate through the nitride film mask to form the pillar semiconductor portions; and

the holes having different depths are formed in first and second openings by depositing the interlayer insulating film to a thickness higher than the nitride film mask, then etching portions of the interlayer insulating film that covers the top of the pillar semiconductor portions of the transistors not interconnected in parallel with each other to form the first opening exposing the nitride film mask on at least two adjacent pillar semiconductor portions, etching the interlayer insulating film on the top of the pillar semiconductor portions of the transistors interconnected with each other to a depth deeper than the first opening to form the second opening exposing the nitride film mask on at least two adjacent pillar semiconductor portions, and removing the nitride film mask.

(Further exemplary embodiment 5) The semiconductor device fabrication method according to Further exemplary embodiment 4, further comprising forming a sidewall nitride film on a sidewall of the holes provided by removing the nitride film mask.

(Further exemplary embodiment 6) The semiconductor device fabrication method according to Further exemplary embodiment 2, wherein the selective epitaxial growth semiconductor film of the transistors not interconnected in parallel with each other is formed at the same time as the selective epitaxial growth semiconductor film of the transistors interconnected in parallel with each other; and

the forming a plurality of pillar semiconductor portions including at least two adjacent pillar semiconductor portions on the principal surface of the semiconductor substrate is performed so that the distance between the pillar semiconductor portions of the two adjacent transistors not interconnected in parallel with each other is greater than the distance between the pillar semiconductor portions of the two adjacent transistors interconnected in parallel with each other by a degree that the selective epitaxial growth semiconductor films of the transistors not interconnected in parallel with each other are not in contact with each other.

(Further exemplary embodiment 7) The semiconductor device fabrication method according to Further exemplary embodiment 6, wherein the forming a plurality of pillar semiconductor portions including at least two adjacent pillar semiconductor portions on the principal surface of the semiconductor substrate comprises forming a nitride film mask on the principal surface of the semiconductor substrate and etching the semiconductor substrate through the nitride film mask to form the pillar semiconductor portions;

the method further comprising:

forming the interlayer insulating film to a thickness higher than the height of the nitride film mask,

etching the interlayer insulating film covering the top of the pillar semiconductor portions until at least portions of the nitride film mask on the pillar semiconductor portions are exposed to form an opening; and

removing the nitride film mask to form holes having the same depth in the opening on the top of the pillar semiconductor portions of the transistors interconnected in parallel with each other and in the opening on the top of the pillar semiconductor portions of the transistors not interconnected with each other;

wherein the depth of the holes is smaller than the amount of epitaxial growth and allows the selective epitaxial growth semiconductor films only on the pillar semiconductor portions of the transistors interconnected in parallel with each other to be in contact with each other in the opening on the hole.

(Further exemplary embodiment 8) The semiconductor device fabrication method according to Further exemplary embodiment 7, further comprising forming a sidewall nitride film on a sidewall of the holes provided by removing the nitride film mask.

(Further exemplary embodiment 9) The semiconductor device fabrication method according to Further exemplary embodiment 1, further comprising forming a contact connecting to a selective epitaxial growth film acting as an continuously formed upper electrode region of the transistors interconnected in parallel with each other and a contact connecting to each of selective epitaxial growth films acting as upper electrode regions of the transistors not interconnected in parallel with each other.

What is claimed is:

1. A semiconductor device including a vertical insulated-gate transistor comprising:
a pillar semiconductor portion provided on a principal surface of a semiconductor substrate;
a gate electrode provided around a side surface of the pillar semiconductor portion via a gate insulating film; and
upper and lower main electrode regions each provided at the upper and bottom of the pillar semiconductor portion;
wherein the upper main electrode region of the transistor comprises a selective epitaxial growth semiconductor film and at least adjacent two of the transistors are interconnected in parallel with each other by joining the selective epitaxial growth semiconductor films of the transistors together.

2. The semiconductor device according to claim 1, further comprising at least two adjacent vertical insulated-gate transistors that are not interconnected in parallel with each other, each comprising a selective epitaxial growth semiconductor film as an upper main electrode region.

3. The semiconductor device according to claim 2, wherein the selective epitaxial growth semiconductor film is grown in a hole formed by exposing the top of the pillar semiconductor portion in an opening formed in a region including at least two transistors in an interlayer insulating film covering the top of the pillar semiconductor portion, and the hole on the top of the pillar semiconductor portion of the transistors interconnected in parallel with each other is shallower than the hole on the top of the pillar semiconductor portion of the transistors not interconnected in parallel with each other.

4. The semiconductor device according to claim 3, wherein the depth of the hole on the top of the pillar semiconductor portion of the transistors interconnected in parallel with each other is smaller than the amount of epitaxial growth and the depth of the hole on the top of the pillar semiconductor portion of the transistors not interconnected in parallel with each other is greater than or equal to the amount of epitaxial growth.

5. The semiconductor device according to claim 2, wherein the distance between the two adjacent transistors interconnected in parallel with each other is smaller than the distance between the two adjacent transistors not interconnected in parallel with each other.

6. The semiconductor device according to claim 5, wherein the selective epitaxial growth semiconductor film is grown in a hole formed by exposing the top of the pillar semiconductor portion in an opening formed in a region including at least two adjacent pillar semiconductor portions in an interlayer insulating film covering the top of the pillar semiconductor region, and the depth of the hole is smaller than the amount of epitaxial growth.

7. The semiconductor device according to claim 1, wherein the vertical insulated-gate transistor is a surrounding gate transistor comprising a gate electrode provided around the entire side surface of the pillar semiconductor portion via a gate insulating film.
